(19) United States
(12) Patent Application Publication
(10) Pub. No.: US 2014/0186583 A1
(43) Pub. Date: Jul. 3, 2014

(54) COATING INCREASING THE FRICTION COEFFICIENT AND PRODUCTION THEREOF BY MEANS OF ATMOSPHERIC PRESSURE PLASMA COATING

(71) Applicant: Willy Speth, Wolnzach (DE)

(72) Inventor: Willy Speth, Wolnzach (DE)

(73) Assignee: IP plasma & brands GmbH, Ingolstadt (DE)

(21) Appl. No.: 14/236,773

(22) PCT Filed: Aug. 2, 2012
(86) PCT No.: PCT/EP2012/003307

§ 371 Date: Feb. 3, 2014

(30) Foreign Application Priority Data
Aug. 5, 2011 (DE) 10 2011 052 447.9

(51) Int. Cl. C23C 16/513; C23C 16/32; F16B 2/00; C23C 16/27

(52) U.S. Cl. CPC C23C 16/513; C23C 16/276; C23C 16/325; F16B 2/005
USPC 428/144; 427/535; 427/577; 427/569

(57) ABSTRACT

The present invention provides an advantageous method for producing a coating (3) increasing the coefficient of friction on a surface (5) of an element (6), wherein the method comprises the following steps: a) activating of hard particles (1) partially or completely covered by a bonding agent (2) in a non-thermal plasma (low-temperature plasma) at atmospheric pressure; and b) producing a layer (3) increasing the coefficient of friction on a surface (5) of the element (6) by depositing the hard particles (1), which are activated by the non-thermal atmospheric pressure plasma and which are coated with the bonding agent onto the surface (5) of the element (6). Specifically, for elements having a complicated shape or having a big size, this method is more efficient than known methods. No matrix or intermediate layers are necessary to fix the hard particles. The anchoring of the hard particles takes place directly in the joining surfaces themselves.

The invention relates to a method for production of a coating increasing the friction coefficient by means of atmospheric pressure plasma coating and to an element with the coating increasing the friction coefficient formed by the before-mentioned method.

For elements and components, frictional connections serve to transmit forces. In particular, in all areas of engineering this kind of connection is used to transmit torque and transverse forces. Therein, adhesive forces determine the amount of the transverse forces which can be transmitted between joining faces which are frictionally connected with each other. The coefficient of friction ν serves as a measure for how high transverse force component relative to a applied normal force can still be applied before sliding occurs. It depends on the pair of materials used for the frictional connection, the roughness, the lubrication condition and the wear of the joining surfaces. The coefficient of friction v for a dry connection of steal surfaces is about 0.15.

An increase of coefficients of friction v can be attained by coatings increasing the friction coefficient. In the prior art there are applied hard particles in a galvanizing bath together with a metal layer serving as a matrix layer onto the surface of an element to produce a coating increasing the friction coefficient. In doing so, the hard particles dispersed in the galvanizing bath are incorporated into the metal layer growing in the galvanizing bath. The material for the hard particles has a higher compressive and shear strength than that of the joining surfaces so that the hard particles allow an additional positive locking (in the range of μm) as they penetrate partially into the surface of the element in case of a respective normal force.

A disadvantage of producing a coating increasing the friction coefficient by continuously incorporating hard particles dispersed in the galvanizing bath into a matrix layer is that the particles incorporated at the end of the coating process are covered by the matrix layer only to a minor degree and that they are, therefore, not firmly anchored therein. Thus, in this method the particles incorporated at the end of the coating process tend to become detached. As a solution to this problem it is proposed in document DE 101 48 831 A1 to use a multi-layer matrix system, in the production of which the galvanizing bath for the last applied matrix layer has no hard particles dispersed therein to ensure that all hard particles are well anchored within the matrix layer system. However, defect areas can occur in multi-layer matrix systems at the interfaces between the matrix layers and this can result in detachment of one or more layers. The detachment of hard particles or of matrix layers causes a big problem for the use of the coated elements in operation as detached hard particles or matrix layers may result in early wear out or in malfunction.

A further disadvantage of producing coatings increasing the friction coefficient in galvanizing bathes for big bulky elements is that also the galvanizing bathes have to be scaled with corresponding large dimensions, and the method thereby becomes costly and uneconomic. Further, surface areas of the elements to be coated, on which no coating increasing the friction coefficient shall be applied have to be elaborately masked in the production of a coating increasing the friction coefficient in a galvanizing bath before dipping the element into the galvanizing bath. When elements have a complicated shape, masking of certain surface areas may even be impossible. To avoid problems in producing a coating increasing the friction coefficient on elements which are big or have a complicated shape it is proposed in document DE 198 23 928 A1 to insert a thin flexible layer with particles incorporated therein as a connecting element between the joining surfaces of a frictional connection instead of depositing coatings increasing the frictional coefficient directly onto the joining surfaces. However, using this separate connecting elements to be inserted between the joining surfaces means an additional effort in mounting of elements for forming a frictional connection.

From document DE 10 2007 043 291 A1 there is known the production of coatings in which a powder used for the coating is activated before applying it onto a substrate by an atmospheric pressure plasma. However, up to now it has not been achieved to thereby deposit coatings increasing the frictional coefficient with high quality.

It is the object of the present invention to produce a coating increasing the friction coefficient on elements with a method which avoids the disadvantages known from the prior art. In particular, it is the object of the invention to provide a more efficient method by which coatings increasing the friction coefficient can be produced which do not involve any danger of detachment of particles and/or of matrix layers.

The object is attained by a manufacturing method according to claim 1. With the method of the invention it is possible in an efficient manner to apply a coating increasing the friction coefficient directly onto the surface of an element also in case of elements which are big and/or have a complicated shape. In the method of the invention preventing applied hard particles from being detached during transport and mounting of the element is attained by a cladding of the hard particle with a bonding agent.

Advantageous developments of the invention are indicated in the dependent claims.

Particularly high coefficients of friction of elements with the coating increasing the coefficient of friction can be attained by using diamond or silicon carbide as a material for the hard particles.

In a preferred embodiment metal is used as bonding agent. A metal cladding is particularly suitable to prevent the hard particles of the coated element surface from being detached early.

Coatings produced by the method of the invention show only little detachment and high coefficients of friction particularly in a preferred embodiment in which the coverage of the hard particles by bonding agent after the coating in method step a) is between 20% and 80% of the hard particle surface. The best results regarding the detachment characteristics and the coefficients of friction are attained if the coverage of the hard particles by bonding agent after the coating in method step a) is between 30% and 70% of the hard particle surface.

In a preferred embodiment the average diameter of the hard particles is between 3 μm and 45 μm. Particularly good characteristics can be attained with an average diameter of the hard particles between 10 μm to 40 μm.

In a preferred embodiment of the method of the invention the coated surface is treated again by atmospheric pressure plasma. Thereby, the detachment characteristics of the coating increasing the coefficient of friction can be further optimized.

In a preferred embodiment of the method of the invention the coating increasing the coefficient of friction as formed in method step b) does not form a closed layer for the element.

Particularly high coefficients of friction can be attained if the coating increasing the coefficient of friction as produced in method step b) on the surface of the element forms a uniform surface coverage with hard particles between 10% and 30% of the surface of the element.

In the following, an embodiment of the invention is explained as an example by means of the attached figures. In the figures:

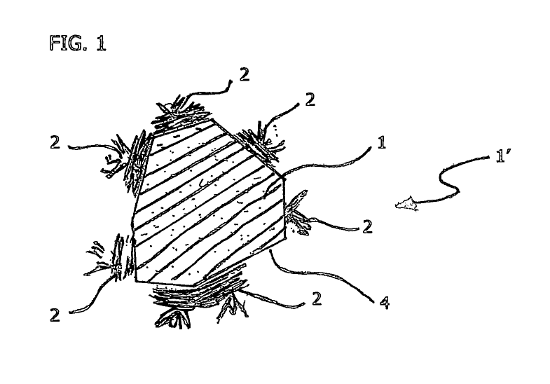

FIG. 1 shows a particle partially coated by a bonding agent as used for producing a coating increasing the coefficient of friction with the method of the invention;

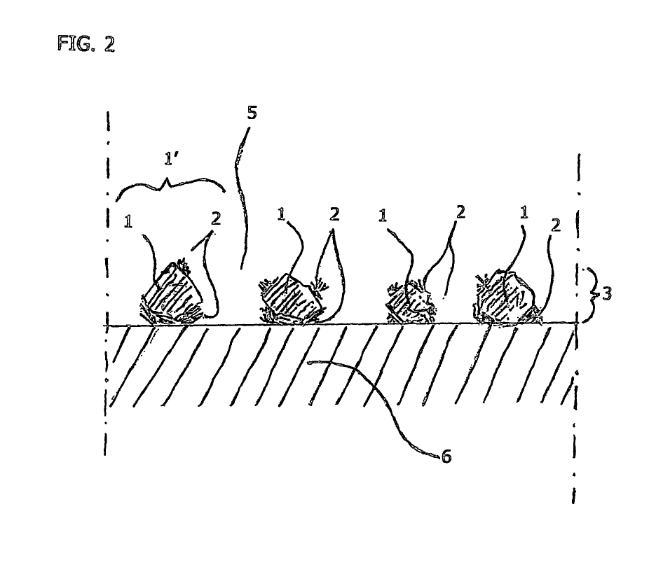

FIG. 2 shows a cross-section of a coating increasing the coefficient of friction as produced by the method of the invention on an element surface intended as joining surface; and

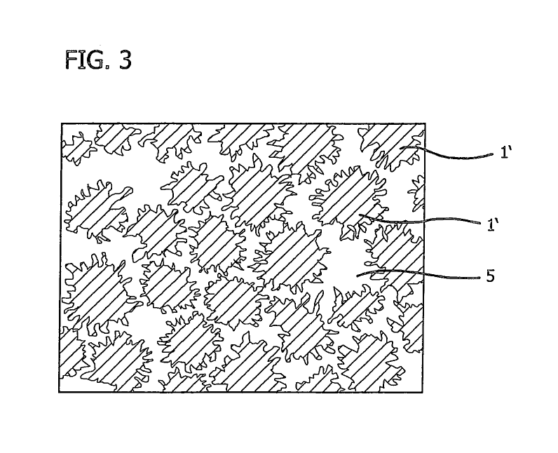

FIG. 3 shows a top view onto the coating increasing the coefficient of friction shown in FIG. 2.

In the method of the invention, hard particles 1 are used which are partially or completely covered by a bonding agent 2. The hard particles 1 are thereby made of a hard material such as diamond, silicon carbide (SiC), boron carbide (B₄C), tungsten carbide (WC), nitrides such as silicon nitride (Si₃N₄) or cubic boron nitride (c-BN), boride, silicon dioxide (SiO₂) or alumina (Al₂O₃). These materials are characterized in that they do not react neither with the material of the components to be joined nor with the ambient medium under the respective conditions of use, which means that they are chemically inert. Further, these materials for the hard particles 1 are characterized in that they have a high compressive and shear strength. It is crucial for the function of the coating 3 increasing the coefficient of friction that the hard particles 1 have a higher compressive and shear strength than the material of the joining surfaces 5, so that the hard particles 1 allow for an additional positive locking by partially penetrating into the element surfaces 5 when the joining surfaces 5 are pressed together as discussed above with the prior art. Preferably, the hard particles 1 are made of silicon carbide or diamond. The average diameter of the hard particles 1 used in the method is 3 μm to 45 μm, preferably 10 μm to 30 μm. The size of the hard particles 1 thereby used results from the target not to damage the joining surfaces 5 by impressing of the hard particles 1 into the joining surfaces to an improper extent. The size distribution of the grain has a variance of not more than ±50% around an indicated nominal diameter.

The bonding agent 2 used for coating the hard particles 1 is made of polymer, metal or an organic substance.

In the present embodiment a metal bonding agent 2 is used which is applied onto the hard particles 1 by means of chemical galvanization. A hard particle partially covered by the bonding agent is shown in FIG. 1. Preferably, the coverage of the hard particles by bonding agent 2 is between 20% and 80% of the hard particle surface 4. In a coverage of the hard particles 1 by bonding agent 2 of less than 20% the hard particles do not adhere reliably to the surface of the element. On the other hand, with a coverage of more than 80% the coefficient of friction becomes low because a too high amount of the bonding agent becomes responsible for sliding properties of the hard particles in the gap between joining surfaces. A coverage between 30% and 70% of the hard particle surface 5 by bonding agent 2 has been shown to be particularly advantageous.

After the hard particles 1 have been partially or completely coated with the bonding agent 2, these coated/covered hard particles 1′ are activated in an atmospheric pressure plasma and the activated hard particles 1′ with the bonding agent cladding 2 are applied onto an element surface to deposit the coating 3 increasing the coefficient of friction, which comprises the hard particles 1 and the bonding agent 2, onto that element surface 5. An apparatus for atmospheric pressure plasma coating is thereby used such as it is described in DE 20 2007 019 184 U1. In the atmospheric plasma coating of the invention the coating powder consisting of the coated hard particles 1′ is mixed with a carrier gas in the absence of ambient air and conveyed into one or a plurality of reaction zones of a plasma jet. In this reaction zone the plasma jet and the carrier gas containing the gas/particle mixture are mixed with each other. Within this/these reaction zone(s) plasma energy is transferred to the stream of gas and particles to a high degree.

The electrons of the plasma jet sputter the metal cladding of the fed powder particles and melt them due to the still relatively high temperature, in particular the high electron temperature, of the plasma there. Due to the energy consumption for the melting and on the further way of the plasma to the nozzle opening cooling down occurs, so that the fine-grained powder forming the coating of the substrate surface arrives at the substrate surface in a cool state. The substrate temperature therefore increases only slightly during the atmospheric pressure plasma coating. The temperature increase of the substrate by the coating process during and directly after the coating process with the fine-grained powder is below 100° C. Therefore, one also refers to a non-thermal atmospheric pressure plasma coating (a non-thermal plasma is also referred to as a low-temperature plasma). Nevertheless a good adhesion is attained by using the non-thermal atmospheric pressure plasma. The substrate surface does not need any specific pre-treatment. The surface cleaning is done by the plasma jet itself.

After the activated mixture of carrier gas and coated hard particles 1′ hit onto the element surface 5 it is coated with the coated hard particles 1′. As the plasma jet itself comes into direct contact with the surface 5 only to a small extent, the structures and properties of the surface 5 to be coated are not damaged and/or permanently affected in the atmospheric pressure plasma coating. The bonding mechanisms between the coating increasing the coefficient of friction consisting of the coated hard particles 1′ and the surface 5 of the element 6 coated therewith is based on the interface effects underlying the atmospheric plasma coating technology. The bonding agent 2 forms the binder between the surface of the element 6 and the hard particle 1. A coating 3 increasing the coefficient of friction which is produced by the method of the invention on an element surface 5 is shown in FIG. 2 in cross-section and FIG. 3 shows a top view of the coating increasing the coefficient of friction shown in FIG. 2.

The adhesion of the hard particles 1 on the coated element surface 5 is further improved after applying the coating 3 increasing the coefficient of friction by a subsequent plasma activation of the surface, in which a plasma jet is in direct contact with the surface to be treated and acts, therefore, directly on the coating 3 increasing the coefficient of friction.

During joining or pressing together of a joining surface 5 of a first element with a joining surface 5 of another element with a coating 3 increasing the coefficient of friction, the hard particles 1 penetrate into the surfaces of the joining surfaces 5 and transmit the occurring transverse forces directly without the bonding agent 2 being involved in this force transmission. The available normal force must be sufficient hereby to press the hard particles 1 into the surface 5 of the elements (joining surfaces). The number of the hard particles 1 per unit area of the contact surfaces of the elements to be joined is preferably between 5% and 40% of the joining surface 5. In case of a smaller coverage of the joining surfaces by hard particles 1 than 5% of the joining surface, the transverse forces to be expected cannot be transmitted reliably. In case of a coverage of more than 40% of the joining surfaces 5 the available normal force is usually not sufficient anymore to press the hard particles 1 deep enough into the joining surfaces 5.

Subsequent to the production of the coating 3 increasing the coefficient of friction as described above, the coating 3 increasing the coefficient of friction is cleared from loosely attached hard particles 1. This can be done e.g. in an ultrasonic bath or by blowing off with pressurized air.

The coating 3 increasing the coefficient of friction produced by the above-described method has a defined number of hard particles 1 which can be reproduced by the method parameters. The coating 3 increasing the coefficient of friction is characterized in that the adhesion to the element surface 5 is effected by the bonding agent 2 attached to the hard particles during and after the coating process. When joining a coated with an uncoated element surface, the hard particles 1 partially penetrate into the joining surfaces 5 and result in a micro positive locking. A significant increase of the achievable transverse and shear forces compared to untreated surfaces of the same pair of materials results thereby.

To apply the coating it is proceeded as follows: The component to be coated (fly wheel) was positioned in an apparatus. Areas of the joining surface to be coated (front side) which shall not come into contact with the coating materials (toothing area) have been protected by methods common for atmospheric pressure plasma coating methods (e.g. shading masks).

During the coating process the fly wheel was moved by means of a xy-moving unit below the coating nozzle of the plasma apparatus at a defined distance and with a defined velocity. The coating process itself took place as described above. By the coating increasing the coefficient of friction produced in such manner the coefficient of friction v could be improved in the specific embodiment by a factor of 4.

In the above embodiment the coating process was described with a xy-moving unit. However, any other handling device, such as a 6-axis robot, can be used. Alternatively, the element to be coated (in the specific embodiment the fly wheel) can be statically positioned on a device and the coating nozzle of a plasma apparatus itself may be moved above the element to be coated.

The above embodiment of the method of the invention was described in such way that the plasma jet itself comes into direct contact with the surface 5 only to a small degree during the deposition itself and that after the deposition itself a subsequent plasma activation is carried out. However, it is also possible to carry out the method in such way that the plasma jet comes into contact with the surface during the deposition. Dependent on time of application of the plasma jet onto the surface during the deposition itself also for this case a subsequent plasma activation might be advantageous.

As a metallic bonding agent nickel was used. However, it is also possible to use other metals as a bonding agent such as copper. Polymers would also be possible to use as a bonding agent as far as they are heat-resisting.

1. A method for producing a coating (3) increasing the coefficient of friction on a surface (5) of an element (6), wherein the method comprises the following steps:
(a) activating of hard particles (1) partially or completely coated with a bonding agent (2) in a non-thermal plasma at atmospheric pressure; and
(b) producing the coating (3) increasing the coefficient of friction on the surface (5) of the element (6) by depositing the hard particles activated by the non-thermal atmospheric plasma and coated by the bonding agent (2) on the surface (5) of the element (6).

2. The method according to claim 1, wherein the hard particles (1) increasing the coefficient of friction are made of diamond, boron carbide or silicon carbide.

3. The method according to claim 1, wherein the bonding agent (2) is a metal or a polymer.

4. The method according to claim 1, wherein the coverage of the hard particles (1) with bonding agent (2) in method step a) is between 20% and 80% of the hard particle surface (4), more preferably between 30% and 70% of the hard particle surface.

5. The method according to claim 1, wherein the hard particles (1) have an average diameter in a range from 3 μm to 45 μm, more preferably in a range from 10 μm to 30 μm.

6. The method according to claim 1, wherein a method comprises the following method step after step b):
(c) post-activating the coated surface (5) by means of an atmospheric pressure plasma.

7. The method according claim 1, wherein the coating (3) increasing the coefficient of friction formed in method step b) does not form a closed layer on the element (6).

8. The method according to claim 1, wherein the coating (3) increasing the coefficient of friction produced in method step b) forms a uniform coverage with hard particles (1) between 5% and 40%, more preferably between 10% and 30% of the surface (5) of the element (6).

9. The method according to claim 1, wherein the temperature increase of the substrate by the coating process during and directly after the coating process is below 100° C.

10. An element with a coating (3) increasing the coefficient of friction, which is produced by the method of claim 1 on the surface (5) of the element (6).
